(19) United States
(12) Patent Application Publication
(10) Pub. No.: US 2026/0273678 A1
(43) Pub. Date: Sep. 17, 2026

(54) PEDESTAL HEATER SUPPORT STRUCTURE

(71) Applicant: Applied Materials, Inc., Santa Clara, CA (US)

(72) Inventor: Frank Wing-Fung CHENG, Sunnyvale, CA (US)

(21) Appl. No.: 19/076,029

(22) Filed: Mar. 11, 2025

(51) Int. Cl. B23Q 3/10

(52) U.S. Cl. CPC B23Q 3/10

(57) ABSTRACT

A support plate for a substrate support includes a disc coupled to an underside of the substrate support. The disc is deformed upon installation such that the disc exerts a biasing force on the underside of the substrate support. The biasing force counteracts a tendency of a peripheral portion of the substrate support to sag.

### BACKGROUND

### Field

Embodiments of the present disclosure generally relate to processing chambers and equipment, such as chambers and equipment for use in manufacturing electronic devices.

### Description of the Related Art

Semiconductor substrates are processed for a wide variety of applications, including the fabrication of integrated devices and microdevices. During processing, the substrate is positioned on a support surface of a substrate support within a processing chamber. In some processes, the substrate is heated by a heater embedded in the substrate support. Typically, the substrate support is mounted to a shaft that is used to raise, lower, and/or rotate the substrate support.

The substrate support is subjected to repeated cycles of heating and cooling during its operational life, and can be subject to flexing. The substrate support is cantilevered on the shaft, and the flexing can include elastic deformation of the substrate support as well as plastic deformation of the substrate support, such as due to creep of the material of construction of the substrate support. The flexing can adversely affect the flatness of the support surface. Anomalies of the flatness of the support surface can be detrimental to chucking of a substrate, heat transfer to the substrate, and the mitigation of defects on the substrate (such as on a backside of the substrate).

Typical measures to alleviate flexing of the substrate support involve changing one or more aspects of the design of the substrate support. However, such measures do not cater for the many thousands of substrate supports currently in use. Thus, there is a need for improved systems that address the above issues.

### SUMMARY

The present disclosure generally relates to substrate processing and components for chambers used in substrate processing. In one aspect, a support plate for a substrate support includes a disc. The disc includes an aperture at a center of the disc. A plurality of projections extends from an upper surface of the disc.

In another aspect, an assembly includes a substrate support and a shaft coupled to the substrate support. The assembly further includes a support plate including a disc disposed around the shaft. The disc is coupled to the substrate support such that the disc exerts a biasing force on an underside of the substrate support.

In another aspect, an assembly includes a substrate support and a shaft coupled to the substrate support. The assembly further includes a support plate coupled to an underside of the substrate support. The support plate includes a disc that includes an aperture through which the shaft is disposed. The support plate further includes a plurality of projections extending from an upper surface of the disc, and in contact with the underside of the substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 schematically illustrates a processing chamber.

FIGS. 2A - 2C schematically illustrate exemplary configurations of a support plate for use in the processing chamber of FIG. 1. The configurations are depicted before and after installation.

FIGS. 2D - 2G schematically illustrate additional exemplary aspects of a support plate for use in the processing chamber of FIG. 1.

FIGS. 3A to 3C schematically illustrate exemplary configurations for coupling a support plate to a substrate support.

FIG. 4 schematically illustrates an exemplary support plate.

FIG. 5 schematically illustrates additional aspects of the support plate of FIG. 4.

FIG. 6 schematically illustrates the coupling of support plate of FIG. 4 to a substrate support.

To facilitate understanding, identical reference numerals have been used, where possible, to designate identical elements that are common to the figures. One or more elements or features of any one embodiment or example may be beneficially incorporated in any one or more other non-mutually exclusive embodiments or examples.

### DETAILED DESCRIPTION

The present disclosure concerns substrate processing and components for chambers used in substrate processing. A pedestal heater, including a substrate support having a heating element and coupled to a shaft, is disposed in a processing chamber. The substrate support is cantilevered on the shaft. A support plate is coupled to the substrate support, and mitigates a tendency of the substrate support to sag due to the cantilever. The support plate is prestressed upon coupling to an underside of the substrate support. The support plate can be retrofitted to pre-existing substrate supports. Use of the support plate negates a need to use thicker substrate supports to combat sagging, which would compromise heat transfer efficiency between the substrate support and a substrate disposed thereon.

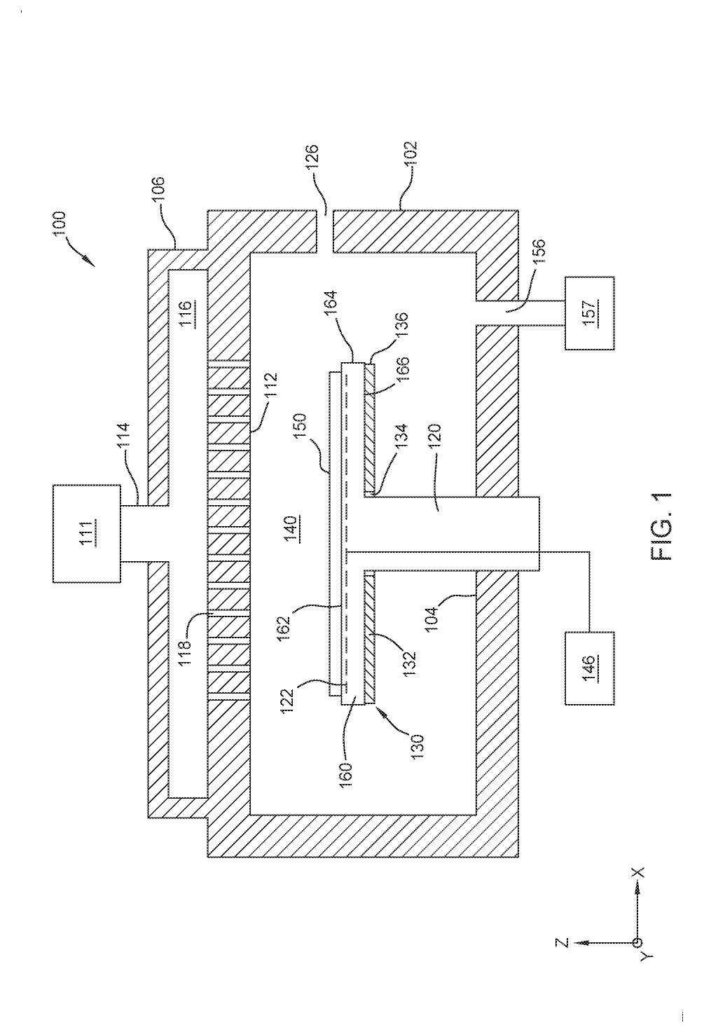

FIG. 1 schematically illustrates a processing chamber 100. In general, the processing chamber 100 can be configured as any one or more of an atomic layer deposition (ALD) chamber, chemical vapor deposition (CVD) chamber, physical vapor deposition (PVD) chamber, epitaxial deposition chamber, ion implantation chamber, etch chamber, degas chamber, ashing chamber, cleaning chamber, a thermal processing chamber (e.g., rapid thermal processing, anneal, cool down, thermal management control), a plasma processing chamber, or other type of substrate processing chamber.

The processing chamber 100 includes a chamber body 102, a substrate support 160 disposed inside the chamber body 102, and a lid 106 coupled to the chamber body 102, and enclosing the substrate support 160 in a processing volume 140. The substrate support 160 includes a support surface 162 configured to receive a substrate 150 thereon for processing. The support surface 162 lies in the X-Y plane. In some embodiments that may be combined with other embodiments, the support surface 162 includes projections in the Z direction (such as mesas) that contact the substrate 150. As illustrated, a heating element 122 is embedded within the substrate support 160. The heating element 122 is coupled to a power source 146. The substrate 150 is provided to the processing volume 140 through an opening 126.

The substrate support 160 is formed from one or more metallic or ceramic materials. Exemplary metallic or ceramic materials include one or more metals, metal oxides, metal nitrides, metal oxynitrides, or any combination thereof. For example, the substrate support 160 may contain or be formed from aluminum, aluminum oxide, aluminum nitride, aluminum oxynitride, or any combination thereof. The substrate support 160 is coupled to a shaft 120 that extends through a floor 104 of the processing chamber 100. The shaft 120 is coupled to an actuator (not shown) that raises and lowers the shaft 120 and the substrate support 160 along the Z direction. In some embodiments that may be combined with other embodiments, the shaft 120 is coupled to another actuator (not shown) that rotates the shaft 120 and the substrate support 160 in the X-Y plane.

A support plate 130 is coupled to an underside of the substrate support 160. The support plate 130 is configured to hinder sagging of peripheral portions of the substrate support 160. In some embodiments that may be combined with other embodiments, the support plate 130 is coupled to the shaft 120. In some embodiments that may be combined with other embodiments, the support plate 130 moves with the shaft 120 along the Z direction. In some embodiments that may be combined with other embodiments, the support plate 130 rotates with the shaft 120 in the X-Y plane.

As illustrated in some embodiments that may be combined with other embodiments, the support plate 130 includes a disc 132 with an aperture 134 at a center of the disc 132. The aperture 134 accommodates the shaft 120. In some embodiments that may be combined with other embodiments, the disc 132 extends a full 360 degrees in the X-Y plane. In some embodiments that may be combined with other embodiments, the disc 132 is a “C” shape that extends less than 360 degrees in the X-Y plane. In some embodiments that may be combined with other embodiments, the disc 132 is a single monolithic body. In some embodiments that may be combined with other embodiments, the disc 132 includes a plurality of bodies, such as sectors of a circle. In some embodiments that may be combined with other embodiments, the disc 132 is made of a metal, such as tungsten or a steel, such as a stainless steel. In some embodiments that may be combined with other embodiments, the disc 132 includes a coating, such as a corrosion-resistant coating.

In some embodiments that may be combined with other embodiments, the disc 132 has a uniform thickness (in the Z direction). In some examples, the thickness of the disc 132 is from 0.5 mm to 5.0 mm, such as 0.5 mm to 4.0 mm, 0.5 mm to 3.0 mm, 0.75 mm to 2.5 mm, 0.75 mm to 2.0 mm, or 1.0 mm to 1.5 mm. In some embodiments that may be combined with other embodiments, the disc 132 has a thickness that varies radially along the X direction and/or the Y direction from the aperture 134 to a periphery 136 of the disc 132. In some examples that may be combined with other examples, the thickness of the disc 132 increases radially along the X direction and/or the Y direction from the aperture 134 to the periphery 136. In some examples that may be combined with other examples, the thickness of the disc 132 decreases radially along the X direction and/or the Y direction from the aperture 134 to the periphery 136.

When the support plate 130 is coupled to the substrate support 160, the support plate 130 is deformed such that the disc 132 contacts an underside 166 of the substrate support 160. The disc 132 is deformed to substantially match the profile of the underside 166 of the substrate support 160. In some examples, the disc 132 is deformed elastically. The deformation of the disc 132 imparts a stress on the disc 132. In some examples, the disc 132 is pre-stressed upon installation at the substrate support 160A such that the disc 132 exerts an upward force along the Z direction on the substrate support 160 at contact points between the disc 132 and the underside 166 of the substrate support 160. For example, at a contact point at a peripheral portion (e.g., the periphery 136) of the disc 132, the disc 132 exerts an upward force along the Z direction on a corresponding peripheral portion (e.g., the periphery 164) of the substrate support 160.

The upward force along the Z direction at each contact point between the disc 132 and the underside 166 of the substrate support 160 counteracts a tendency of the substrate support 160 to sag. In some embodiments that may be combined with other embodiments, the upward force along the Z direction exerted at the periphery 164 of the substrate support 160 is greater than an upward force along the Z direction exerted at one or more other contact points between the periphery 164 and the shaft 120. The upward force along the Z direction exerted at the periphery 164 of the substrate support 160 is a biasing force that counteracts a tendency of the periphery 164 of the substrate support 160 to sag.

An exhaust port 156 in the processing chamber 100 is coupled to a vacuum pump 157. The vacuum pump 157 removes excess process gases or by-products from the processing volume 140 via the exhaust port 156 during and/or after processing.

A gas supply source 111 includes one or more gas sources. The gas supply source 111 is configured to deliver the one or more gases from the one or more gas sources to the processing volume 140. Each of the one or more gas sources provides a processing gas, such as a precursor, a carrier gas, a purge gas, a cleaning gas, or the like. In some embodiments that may be combined with other embodiments, a remote plasma source can be used to deliver plasma to the processing chamber 100, and can be coupled to the gas supply source 111.

A showerhead 112 features openings 118 for admitting process gases into the processing volume 140 from the gas supply source 111. The process gases are supplied to the processing chamber 100 via a gas feed 114, and the process gases enter a plenum 116 prior to flowing through the openings 118. In some embodiments that may be combined with other embodiments, different process gases that are flowed simultaneously during a processing operation enter the processing chamber 100 via separate gas feeds and separate plenums prior to entering the processing volume 140 through the showerhead 112.

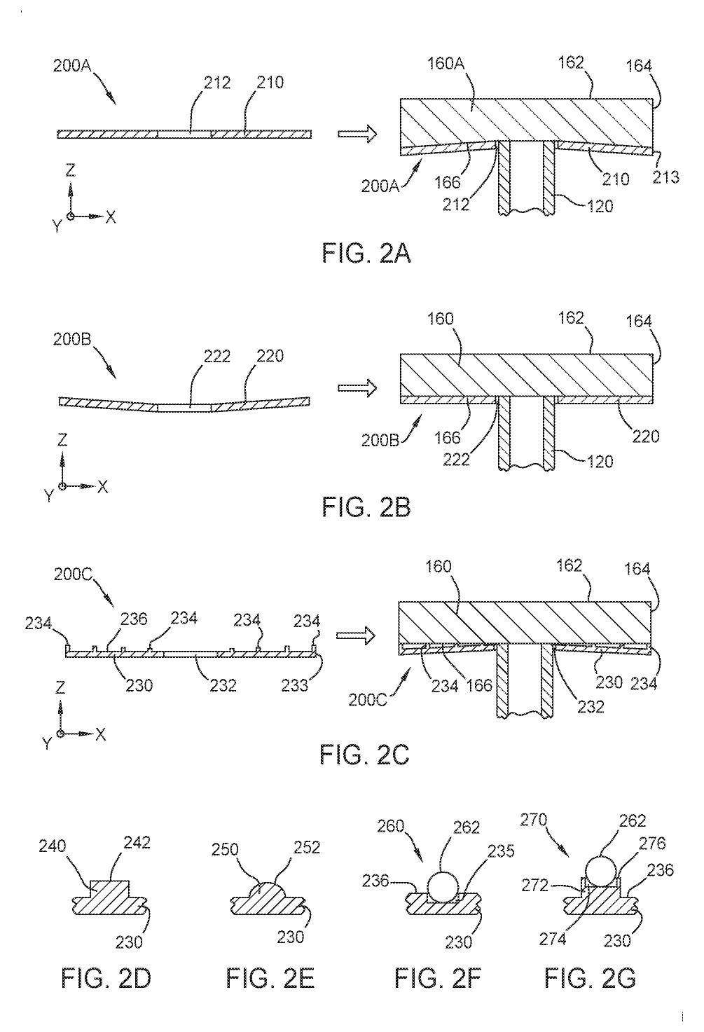

FIGS. 2A to 2C schematically illustrate cross-sections of exemplary configurations of the support plate 130. In each of FIGS. 2A to 2C, the support plate 130 is depicted in both a free state and an as-installed state. The free state represents a normal, undeformed, state of the support plate 130 when not subjected to external forces (except gravity) prior to being coupled to the substrate support 160. The as-installed state represents the support plate 130 when coupled to the substrate support 160.

In FIG. 2A, the support plate 130 is represented by support plate 200A. Support plate 200A includes a disc 210 with an aperture 212 that accommodates the shaft 120. The disc 210 is flat in the X-Y plane in the free state. The substrate support 160 is represented substrate support 160A. Substrate support 160A includes the support surface 162, which lies in the X-Y plane. The substrate support 160A has a thickness that increases from the shaft 120 to the periphery 164 of the substrate support 160A. The underside 166 of the substrate support 160A has a concave (e.g., frustoconical) profile.

When the support plate 200A is coupled to the substrate support 160A, the support plate 200A is deformed such that the disc 210 contacts the underside 166 of the substrate support 160A. The disc 210 is deformed in the Z direction to substantially match the concave profile of the underside 166 of the substrate support 160A. In some examples, the periphery 213 of the disc 210 is deformed in the Z direction relative to a center of the disc 210 by 0.1 mm to 5.0 mm, such as by 0.5 mm to 4.5 mm, 1.0 mm to 4.0 mm, 1.5 mm to 3.5 mm, or 2.0 mm to 3.0 mm. The deformation of the disc 210 creates the prestressing of the disc 210, as described above. The prestressing of the disc 210 causes the disc 210 to exert upward forces along the Z direction on the substrate support 160A at contact points between the disc 210 and the underside 166 of the substrate support 160A, as described above.

In FIG. 2B, the support plate 130 is represented by support plate 200B. Support plate 200B includes a disc 220 with an aperture 222 that accommodates the shaft 120. The disc 220 has a concave (e.g., frustoconical) profile in the free state. The substrate support 160 includes the support surface 162, which lies in the X-Y plane. The substrate support 160 has a thickness that is substantially uniform from the shaft 120 to the periphery 164 of the substrate support 160. The underside 166 of the substrate support 160 is substantially flat in the X-Y plane.

When the support plate 200B is coupled to the substrate support 160, the support plate 200B is deformed such that the disc 220 contacts the underside 166 of the substrate support 160. The disc 220 is deformed in the Z direction to substantially match the profile of the underside 166 of the substrate support 160. In some examples, the periphery 223 of the disc 220 is deformed in the Z direction relative to a center of the disc 220 by 0.1 mm to 5.0 mm, such as by 0.5 mm to 4.5 mm, 1.0 mm to 4.0 mm, 1.5 mm to 3.5 mm, or 2.0 mm to 3.0 mm. The deformation of the disc 220 creates the prestressing of the disc 220, as described above. The prestressing of the disc 220 causes the disc 220 to exert upward forces along the Z direction on the substrate support 160 at contact points between the disc 220 and the underside 166 of the substrate support 160, as described above.

In FIG. 2C, the support plate 130 is represented by support plate 200C. Support plate 200C includes a disc 230 with an aperture 232 that accommodates the shaft 120. As illustrated, in some embodiments that may be combined with other embodiments, the disc 230 is flat in the X-Y plane in the free state. Nevertheless, in some embodiments that may be combined with other embodiments, the disc 230 has a concave (e.g., frustoconical) profile in the free state.

The support plate 200C includes one or more projections 234 on an upper surface 236 of the disc 230. In some embodiments that may be combined with other embodiments, at least one of the one or more projections 234 is in the form of a continuous ring in the X-Y plane. In some embodiments that may be combined with other embodiments, at least one of the one or more projections 234 is not in the form of a continuous ring in the X-Y plane.

In some embodiments that may be combined with other embodiments, at least one of the one or more projections 234 is integral with the disc 230. In some examples, the disc 230 is machined to create at least one of the one or more projections 234 such that the disc 230 and the projection 234 form a monolithic body. In some embodiments that may be combined with other embodiments, at least one of the one or more projections 234 is a separate item that is attached to the disc 230, such as by welding, brazing, gluing, screwing into the disc 230, or by using a fastener (e.g., a nut, a screw, a bolt, a rivet, a retaining clip, or the like).

In some embodiments that may be combined with other embodiments, each projection 234 extends to a similar height in the Z direction above the upper surface 236 of the disc 230. As illustrated, in some embodiments that may be combined with other embodiments, at least one projection 234 extends to a different height than another projection 234 in the Z direction above the upper surface 236 of the disc 230. As illustrated, in some embodiments that may be combined with other embodiments, the height of the projections 234 in the Z direction above the upper surface 236 of the disc 230 increases from the aperture 232 to a periphery 233 of the disc 230.

The substrate support 160 includes the support surface 162, which lies in the X-Y plane. The substrate support 160 has a thickness that is substantially uniform from the shaft 120 to the periphery 164 of the substrate support 160. The underside 166 of the substrate support 160 is substantially flat in the X-Y plane.

When the support plate 200C is coupled to the substrate support 160, the support plate 200C is deformed such that the disc 230 contacts the underside 166 of the substrate support 160. The disc 230 is deformed in the Z direction such that the one or more projections 234 contact the underside 166 of the substrate support 160. In some examples, the periphery 233 of the disc 230 is deformed in the Z direction relative to a center of the disc 230 by 0.1 mm to 5.0 mm, such as by 0.5 mm to 4.5 mm, 1.0 mm to 4.0 mm, 1.5 mm to 3.5 mm, or 2.0 mm to 3.0 mm. The deformation of the disc 230 creates the prestressing of the disc 230, as described above. The prestressing of the disc 230 causes the disc 230 to exert upward forces along the Z direction on the substrate support 160 at contact points between the one or more projections 234 and the underside 166 of the substrate support 160, as described above.

The one or more projections 234 provide a smaller total contact area between the substrate support 160 and the disc 230 than between the substrate support 160 and the disc 220 or between the substrate support 160A and the disc 210. The smaller total contact area results in a comparative reduction in the rate of heat transfer between the substrate support 160 and the disc 230 compared to the disc 220 or the disc 210, and a consequential improvement in substrate 150 heating efficiency.

In some embodiments that may be combined with other embodiments, the support plate 200A includes one or more features of the support plate 200C. In some embodiments that may be combined with other embodiments, the support plate 200B includes one or more features of the support plate 200C.

FIGS. 2D to 2G schematically illustrate cross-sections of examples of the one or more projections 234. In FIG. 2D, the projection 234 is represented by projection 240. Projection 240 includes a top surface 242 that is substantially planar. In some embodiments that may be combined with other embodiments, the top surface 242 is rounded at the edges of the projection 240. In some embodiments that may be combined with other embodiments, the top surface 242 is planar in the X-Y plane. In some embodiments that may be combined with other embodiments, the top surface 242 is planar in a plane that intersects the X-Y plane at an acute angle. In some examples, the top surface 242 makes a planar contact with the underside 166 of the substrate support 160 when coupled to the substrate support 160.

In FIG. 2E, the projection 234 is represented by projection 250. Projection 250 includes a top surface 252 that is curved. The top surface 252 is convex. In some embodiments that may be combined with other embodiments, the projection 250 is shaped as a portion of an ellipsoid, such as a portion of a sphere. In some examples, the top surface 252 makes a limited areal contact (such as a point contact) with the underside 166 of the substrate support 160 when coupled to the substrate support 160. In some embodiments that may be combined with other embodiments, the projection 250 is shaped as a portion of a cylinder, such as a circular or elliptical cylinder. In some examples, the top surface 252 makes a limited areal contact (such as a line contact) with the underside 166 of the substrate support 160 when coupled to the substrate support 160.

In FIG. 2F, the projection 234 is represented by projection 260. Projection 260 includes a bearing 262 partially disposed in a recess 235 in the upper surface 236 of the disc 230. In some embodiments that may be combined with other embodiments, the bearing 262 is a ball. In some embodiments that may be combined with other embodiments, the bearing 262 is a cylinder.

The bearing 262 accommodates relative movement between the substrate support 160 and the disc 230 during heating and cooling of the substrate support 160. In some examples that may be combined with other examples, the substrate support 160 and the disc 230 heat or cool at different rates, and expand or contract at different rates. In some examples that may be combined with other examples, the substrate support 160 and the disc 230 are made from different materials (as described above) having different coefficients of thermal expansion, and so expand or contract at different rates.

In some embodiments that may be combined with other embodiments, the bearing 262 is made of a metal, such as aluminum, tungsten, or a steel, such as a stainless steel. In some embodiments that may be combined with other embodiments, the bearing 262 is made of a ceramic, such as an aluminum oxide, silicon nitride, zirconium oxide, or tungsten carbide. In some embodiments that may be combined with other embodiments, the bearing 262 is made of the same material as the substrate support 160. In some embodiments that may be combined with other embodiments, the bearing 262 is made of the same material as the disc 230. In some embodiments that may be combined with other embodiments, the bearing 262 includes a coating, such as a corrosion-resistant coating.

In FIG. 2G, the projection 234 is represented by projection 270. Projection 270 includes the bearing 262 coupled to a member, such as holder 272. The holder 272 extends in the Z direction from the upper surface 236 of the disc 230. The bearing 262 is partially disposed in a recess 274 in the upper surface 276 of the holder 272.

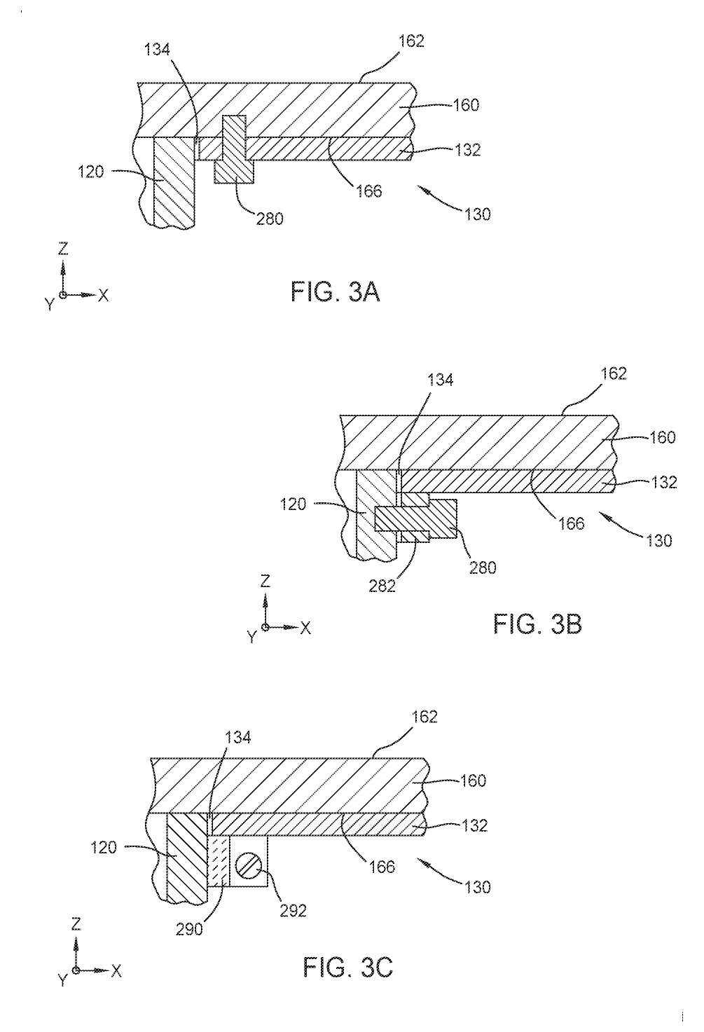

FIGS. 3A - 3C schematically illustrate exemplary configurations for coupling the support plate 130 to the substrate support 160. In FIG. 3A, the support plate 130 is coupled to the underside 166 of the substrate support 160 by one or more fasteners 280, such as a nut, a screw, a bolt, a rivet, a retaining clip, or the like. In some embodiments that may be combined with other embodiments, a spacer (such as a washer or a shim) is interposed between the support plate 130 and the substrate support 160. In some examples, a thickness of the spacer is selected according to a predetermined force to be applied by the support plate 130 to the substrate support 160 resulting from the prestressing of the support plate 130. As illustrated, in some embodiments that may be combined with other embodiments, the spacer is omitted.

In FIG. 3B, the support plate 130 is held against the underside 166 of the substrate support 160 by one or more brackets 282. Each of the one or more brackets 282 is coupled to the shaft 120 by one or more corresponding fasteners 280. In some embodiments that may be combined with other embodiments, a first spacer (such as a washer or a shim) is interposed between each bracket 282 and the support plate 130. In some embodiments that may be combined with other embodiments, a second spacer (such as a washer or a shim) is interposed between the support plate 130 and the substrate support 160. In some examples, a thickness of the first or second spacers is selected according to a predetermined force to be applied by the support plate 130 to the substrate support 160 resulting from the prestressing of the support plate 130. As illustrated, in some embodiments that may be combined with other embodiments, the first and second spacers are omitted.

In FIG. 3C, the support plate 130 is held against the underside 166 of the substrate support 160 by a clamp 290. The clamp 290 is tightened around the shaft 120 by one or more clamp screws 292. In some embodiments that may be combined with other embodiments, a first spacer (such as a washer or a shim) is interposed between the clamp 290 and the support plate 130. In some embodiments that may be combined with other embodiments, a second spacer (such as a washer or a shim) is interposed between the support plate 130 and the substrate support 160. In some examples, a thickness of the first or second spacers is selected according to a predetermined force to be applied by the support plate 130 to the substrate support 160 resulting from the prestressing of the support plate 130. As illustrated, in some embodiments that may be combined with other embodiments, the first and second spacers are omitted.

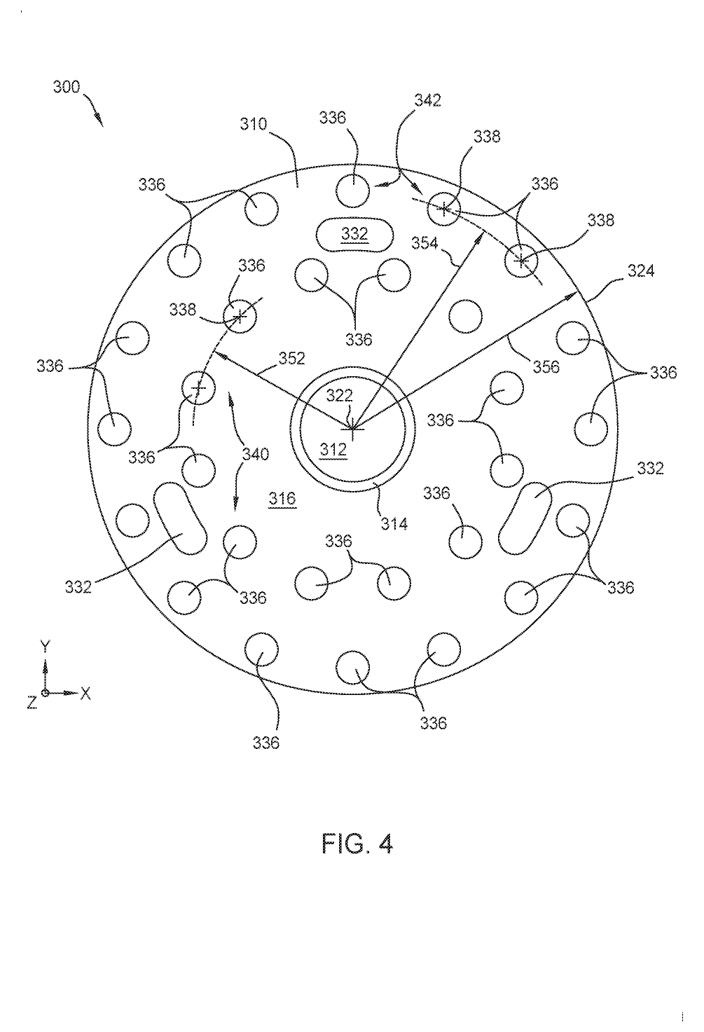

FIG. 4 schematically illustrates a plan view of an exemplary configuration of the support plate 130. The support plate 130 is represented by support plate 300. Support plate 300 includes a disc 310 with an aperture 312 that accommodates the shaft 120. In some embodiments that may be combined with other embodiments, the disc 310 includes a lip 314 around the aperture 312 that extends in the Z direction from the upper surface 316 of the disc 310. In some embodiments that may be combined with other embodiments, the lip 314 is omitted.

The disc 310 includes a plurality of openings 332 (three are illustrated) that are configured to accommodate one or more components of a lift pin system. In some examples that may be combined with other examples, each opening 332 is configured to accommodate a lift pin that will extend therethrough once the support plate 300 is coupled to the substrate support 160. In some examples that may be combined with other examples, each opening 332 is configured to accommodate a lift pin holder that will extend therethrough once the support plate 300 is coupled to the substrate support 160.

As illustrated, the disc 310 includes a first array 340 of holes 336. The center 338 of each hole 336 of the first array 340 is at a radius 352 from the center 322 of the disc 310. In some embodiments that may be combined with other embodiments, a magnitude of the radius 352 is 50% or more of a magnitude of a radius 356 from the center 322 of the disc 310 to the periphery 324 of the disc 310. In some examples, the magnitude of radius 352 is 50% to 90% of the magnitude of radius 356, such as 50% to 85%, 55% to 80 %, 60% to 75%, or 65% to 70% of the magnitude of radius 356.

As illustrated, the disc 310 includes a second array 342 of holes 336. The center 338 of each hole 336 of the second array 342 is at a radius 354 from the center 322 of the disc 310. In some embodiments that may be combined with other embodiments, a magnitude of the radius 354 is 70% or more of a magnitude of the radius 356, such as 70% to 95%, 75% to 90%, or 80% to 85% of a magnitude of the radius 356. In some embodiments that may be combined with other embodiments, the disc 310 includes one or more additional arrays of holes 336, such as between the aperture 312 and the first array 340 of first holes 336.

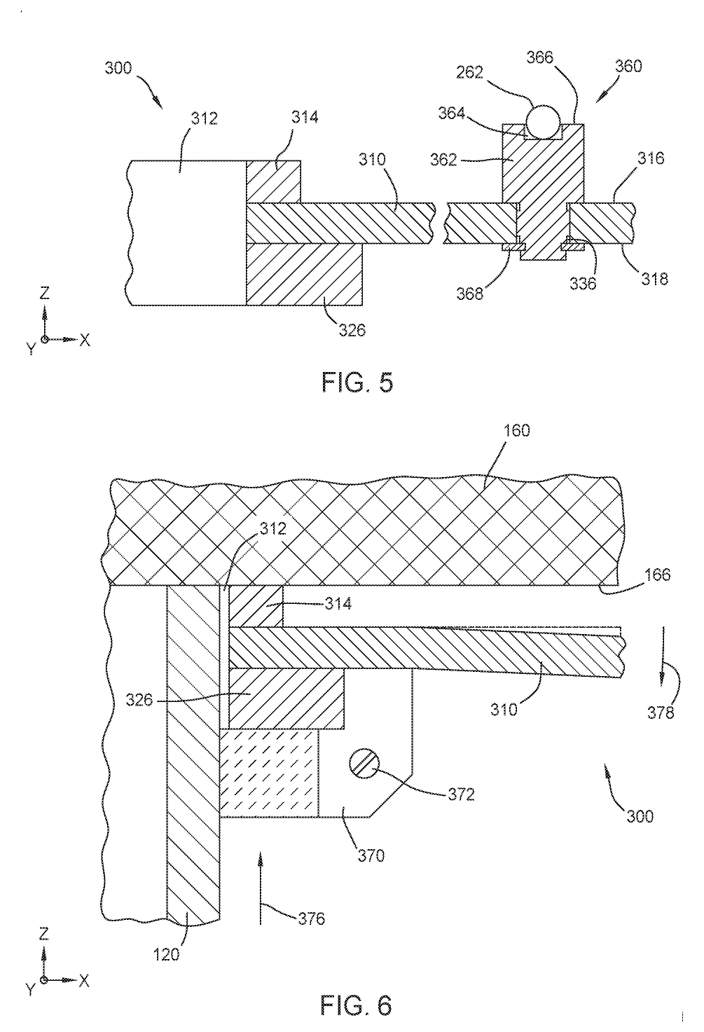

FIG. 5 schematically illustrates additional aspects of the support plate 300 in a lateral cross-sectional view. In some embodiments that may be combined with other embodiments, the disc 310 includes a collar 326 around the aperture 312 that extends in the Z direction from the lower surface 318 of the disc 310. In some examples that may be combined with other examples, the disc 310 is machined such that the lip 314 or the collar 326 are integral with the disc 310 as a monolithic body. In some examples that may be combined with other examples, the lip 314 or the collar 326 are attached to the disc 310, such as by welding, brazing, gluing, screwing into the disc 310, or by using a fastener (e.g., a nut, a screw, a bolt, a rivet, a retaining clip, or the like). In some embodiments that may be combined with other embodiments, the collar 326 is omitted.

An exemplary projection (234, FIG. 2C) is represented by projection unit 360. Projection unit 360 is similar to projection 270 (FIG. 2G), and includes the bearing 262 coupled to a member, such as holder 362. The holder 362 extends in the Z direction from the upper surface 316 of the disc 310. As illustrated, in some embodiments that may be combined with other embodiments, the holder 362 extends through the hole 336, and is secured to the disc 310 by a fastener 368, such as a nut, a screw, a bolt, a rivet, a retaining clip, or the like. In some embodiments that may be combined with other embodiments, the holder 362 is secured to the disc 310 by welding, brazing, gluing, or by screwing into the disc 310. The bearing 262 is partially disposed in a recess 364 in the upper surface 366 of the holder 362.

When the projection units 360 are installed in the holes 336, the projection units 360 form a first array corresponding to the first array 340 of holes 336, and a second array corresponding to the second array 342 of holes 336. A center of each projection unit 360 of the first array of projections units 360 is at the radius 352 from the center 322 of the disc 310. A center of each projection unit 360 of the second array of projections units 360 is at the radius 354 from the center 322 of the disc 310. In some embodiments that may be combined with other embodiments, the number of projection units 360 is equal to the number of holes 336. In some embodiments that may be combined with other embodiments, the number of projection units 360 is less than the number of holes 336.

In some embodiments that may be combined with other embodiments, each projection unit 360 extends by the same distance in the Z direction from the upper surface 316 of the disc 310. In some embodiments that may be combined with other embodiments, the projection units 360 coupled to the second array 342 of holes 336 extend in the Z direction from the upper surface 316 of the disc 310 by a greater distance than the projection units 360 coupled to the first array 340 of holes 336.

FIG. 6 schematically illustrates the coupling of the support plate 300 to the substrate support 160 using a clamp 370. The shaft 120 is inserted through the aperture 312 of the disc 310 of the support plate 300 such that the support plate 300 is placed around the shaft 120 with the upper surface 316 of the disc 310 facing the underside 166 of the substrate support 160. The clamp 370 is placed around the collar 326. The support plate 300 is positioned such that the projection units (360, FIG. 5) contact the underside 166 of the substrate support 160.

A force (shown by arrow 376) along the Z direction towards the substrate support 160 is applied to the clamp 370 to move the lip 314 into contact with the underside 166 of the substrate support 160. Because the projection units (360, FIG. 5) are in contact with the underside 166 of the substrate support 160, the force 376 causes deformation of the disc 310, as shown by the arrow 378. The deformation 378 of the disc 310 creates the prestressing of the disc 310, as described above. The clamp 370 is secured around the shaft 120, such as by tightening a clamp screw 372. In some embodiments that may be combined with other embodiments, the clamp 370 includes a ratchet or a lock ring that has inwardly-projecting teeth that engage corresponding teeth on the shaft 120.

Embodiments of the present disclosure provide a support plate that can be coupled to a substrate support to mitigate a tendency of the substrate support to sag. The support plate can be retrofitted to pre-existing substrate supports. Use of the support plate negates a need to use thicker substrate supports to combat sagging, which would compromise heat transfer efficiency between the substrate support and a substrate disposed thereon.

It is contemplated that any one or more elements or features of any one disclosed embodiment or example may be beneficially incorporated in any one or more other non-mutually exclusive embodiments or examples. While the foregoing is directed to embodiments of the present disclosure, other and further embodiments of the disclosure may be devised without departing from the basic scope thereof, and the scope thereof is determined by the claims that follow.

What is claimed is:

1. A support plate for a substrate support, the support plate comprising:
a disc;
an aperture at a center of the disc; and
a plurality of projections extending from an upper surface of the disc.

2. The support plate of claim 1, wherein the plurality of projections are integral with the upper surface of the disc such that the disc and the plurality of projections form a monolithic structure.

3. The support plate of claim 1, wherein each projection of the plurality of projections includes a bearing disposed in a recess.

4. The support plate of claim 1, wherein each projection of the plurality of projections includes a member disposed in a corresponding hole in the disc.

5. The support plate of claim 4, wherein each projection of the plurality of projections includes a bearing disposed in a recess in the member.

6. The support plate of claim 1, wherein the plurality of projections includes:
a first array of projections disposed at a first radius from the center of the disc; and
a second array of projections disposed at a second radius from the center of the disc, the second radius greater that the first radius.

7. The support plate of claim 6, wherein:
each projection of the first array of projections extends by a first distance from the upper surface of the disc; and
each projection of the second array of projections extends by a second distance from the upper surface of the disc, the second distance greater that the first distance.

8. An assembly, comprising:
a substrate support;
a shaft coupled to the substrate support; and
a support plate including a disc disposed around the shaft, and coupled to the substrate support, such that the disc exerts a biasing force on an underside of the substrate support.

9. The assembly of claim 8, wherein the disc exerts the biasing force on the underside of the substrate support at a peripheral portion of the substrate support.

10. The assembly of claim 8, wherein prestressing of the disc upon coupling the disc to the substrate support causes the disc to exert the biasing force on the underside of the substrate support.

11. The assembly of claim 10, wherein deformation of the disc upon coupling the disc to the substrate support causes the prestressing of the disc.

12. The assembly of claim 11, wherein the disc is elastically deformed from a free state upon coupling the disc to the underside of the substrate support.

13. The assembly of claim 8, wherein the disc includes a collar that extends from a lower surface of the disc.

14. The assembly of claim 13, further comprising a clamp disposed around the collar and around the shaft.

15. The assembly of claim 8, wherein the disc includes a plurality of projections extending from an upper surface of the disc and contacting the underside of the substrate support.

16. An assembly, comprising:
a substrate support;
a shaft coupled to the substrate support; and
a support plate coupled to an underside of the substrate support, the support plate including a disc, the disc including:
an aperture through which the shaft is disposed; and
a plurality of projections extending from an upper surface of the disc, and in contact with the underside of the substrate support.

17. The support plate of claim 16, wherein each projection of the plurality of projections includes a member disposed in a corresponding hole in the disc.

18. The support plate of claim 17, wherein each projection of the plurality of projections includes a bearing disposed in a recess in the member.

19. The support plate of claim 16, wherein the plurality of projections includes:
a first array of projections disposed at a first radius from a center of the disc; and
a second array of projections disposed at a second radius from the center of the disc, the second radius greater that the first radius.

20. The support plate of claim 19, wherein:
each projection of the first array of projections extends by a first distance from the upper surface of the disc; and
each projection of the second array of projections extends by a second distance from the upper surface of the disc, the second distance greater that the first distance.
